(19) United States
(12) Patent Application Publication
(10) Pub. No.: US 2024/0363549 A1
(43) Pub. Date: Oct. 31, 2024

(54) ELECTRONIC DEVICE

(71) Applicant: Innolux Corporation, Miaoli County (TW)

(72) Inventors: Wei-Yuan Cheng, Miaoli County (TW); Ju-Li Wang, Miaoli County (TW)

(73) Assignee: Innolux Corporation, Miaoli County (TW)

(21) Appl. No.: 18/613,040

(22) Filed: Mar. 21, 2024

Related U.S. Application Data
(60) Provisional application No. 63/461,595, filed on Apr. 25, 2023.

(30) Foreign Application Priority Data
Jan. 8, 2024 (CN) 202410024586.9

(51) Int. Cl. H01L 23/00; H01L 21/48; H01L 23/367; H01L 23/538; H01L 25/16

(52) U.S. Cl. CPC H01L 23/562; H01L 21/4846; H01L 23/367; H01L 23/5384; H01L 23/5386; H01L 24/32; H01L 24/33; H01L 25/16; H01L 24/13; H01L 24/16; H01L 24/73; H01L 2224/13105; H01L 2224/13111; H01L 2224/13139; H01L 2224/13144; H01L 2224/13147; H01L 2224/13155; H01L 2224/16227; H01L 2224/32225; H01L 2224/32245; H01L 2224/33181; H01L 2224/73204

(57) ABSTRACT

An electronic device includes a substrate, a circuit layer, at least one electronic unit, a stress adjustment layer, and a buffer layer. The substrate has a first surface and a second surface opposite to each other and at least one side connected to the first surface and the second surface. The circuit layer is disposed on the first surface of the substrate. The at least one electronic unit is electronically connected to the circuit layer. The stress adjustment layer is disposed on the second surface of the substrate. The buffer layer surrounds the substrate, wherein the stress adjustment layer is located between the substrate and the buffer layer, and the buffer layer is in contact with the at least one side of the substrate.

### CROSS-REFERENCE TO RELATED APPLICATION

This application claims the priority benefits of U.S. provisional application Ser. No. 63/461,595, filed on Apr. 25, 2023, and China application serial no. 202410024586.9, filed on Jan. 8, 2024. The entirety of each of the above-mentioned patent applications is hereby incorporated by reference herein and made a part of this specification.

### BACKGROUND OF THE DISCLOSURE

### Technical Field

The disclosure relates to an electronic device, and in particular, to an electronic device that may effectively improve signal transmission quality.

### Description of Related Art

In current techniques, systems that need to transmit signals quickly, such as base IC or memory, are integrated into the package to form a system in package (SiP), or increase the input/output (I/O) number of the base IC via Fan-Out Wafer Level Packaging (FOWLP) and then electrically connect more systems with Package on Package (POP). The system requires connecting other elements such as a plurality of system packages and passive elements to the printed circuit board via a connecting element, and the electrical connection of the stacked package also requires a connecting element. Therefore, the condition of the joint of the connecting element and copper affects the reliability of the electronic device or affects the signal transmission quality of the electronic device.

### SUMMARY

The disclosure provides an electronic device that may effectively improve signal transmission quality.

An electronic device of the disclosure includes a substrate, a circuit layer, at least one electronic unit, a stress adjustment layer, and a buffer layer. The substrate has a first surface and a second surface opposite to each other and at least one side connected to the first surface and the second surface. The circuit layer is disposed on the first surface of the substrate. The at least one electronic unit is electronically connected to the circuit layer. The stress adjustment layer is disposed on the second surface of the substrate. The buffer layer surrounds the substrate, wherein the stress adjustment layer is located between the substrate and the buffer layer, and the buffer layer is in contact with the at least one side of the substrate.

Based on the above, in an embodiment of the disclosure, the circuit layer and the stress adjustment layer are respectively disposed on the first surface and the second surface of the substrate, the electronic unit is electrically connected to the circuit layer, the stress adjustment layer is located between the substrate and the buffer layer, and the buffer layer surrounds the substrate and is in contact with at least one side of the substrate. Via the above design, the joint strength between elements may be improved, or the distance between elements may be shorter, thereby improving the signal transmission quality of the electronic device. Furthermore, since the electronic device of an embodiment of the disclosure is provided with the stress adjustment layer, board warpage may be effectively reduced and structural reliability may be increased. In addition, the electronic device of an embodiment of the disclosure is provided with the buffer layer to provide buffering to effectively reduce breakage of the substrate due to impact.

In order to make the aforementioned features and advantages of the disclosure more comprehensible, embodiments accompanied with figures are described in detail below.

### BRIEF DESCRIPTION OF THE DRAWINGS

FIG. 1 is a schematic cross-sectional view of an electronic device of an embodiment of the disclosure.

FIG. 2 is a schematic cross-sectional view of an electronic device of another embodiment of the disclosure.

FIG. 3 is a schematic cross-sectional view of an electronic device of another embodiment of the disclosure.

FIG. 4 is a schematic cross-sectional view of an electronic device of another embodiment of the disclosure.

FIG. 5 is a schematic cross-sectional view of an electronic device of another embodiment of the disclosure.

FIG. 6 is a schematic cross-sectional view of an electronic device of another embodiment of the disclosure.

FIG. 7 is a schematic cross-sectional view of an electronic device of another embodiment of the disclosure.

FIG. 8A to FIG. 8E are schematic diagrams of a manufacturing method of an electronic device of an embodiment of the disclosure.

### DESCRIPTION OF THE EMBODIMENTS

Reference will now be made in detail to the exemplary embodiments of the disclosure, and examples of the exemplary embodiments are illustrated in the accompanying drawings. Wherever possible, the same reference numerals are used in the figures and the descriptions to refer to the same or similar portions.

The disclosure may be understood by referring to the following detailed description in combination with the accompanying drawings. It should be noted that in order to make it easy for readers to understand and for the simplicity of the drawings, many of the drawings in the disclosure depict portions of the electronic device, and certain elements in the drawings are not drawn to actual scale. In addition, the number and size of elements in the figures are for illustration and are not intended to limit the scope of the disclosure.

Throughout the disclosure, certain words are used to refer to specific elements in the specification and the claims. Those skilled in the art should understand that electronic equipment manufacturers may refer to the same elements by different names. The specification does not intend to distinguish between elements having the same function but different names.

In the following description and claims, the words “contain” and “include” and the like are open-ended words, and therefore should be interpreted as “including but not limited to . . . ”

In addition, relative terms, such as “below” or “bottom” and “above” or “top”, may be used in the embodiments to describe the relative relationship of one element of the figure to another element. It may be understood that if the device in the figures is turned upside down, elements described as being on the “lower” side are then elements described as being on the “upper” side.

In some embodiments of the disclosure, terms related to joining and connecting such as “connection”, “interconnection”, etc., unless otherwise defined, may mean that the two structures are in direct contact, or may also mean that the two structures are not in direct (indirect) contact, wherein there are other structures provided between the two structures. Moreover, the terms about joining and connecting may also include the situation where both structures are movable, or both structures are fixed. Moreover, the term “coupling” includes the transfer of energy between two structures via direct or indirect electrical connection means, or the transfer of energy between two separate structures via mutual induction means.

It should be understood that when an element or layer is referred to as being “on” or “connected to” another element or layer, it may be directly on or directly connected to the other element or layer, or there may be an intervening element or layer between the two (indirect cases). In contrast, when an element is referred to as being “directly on” or “directly connected to” another element or layer, there are no intervening elements or layers present.

The terms “about”, “equal to”, “equal” or “same”, “substantially” or “essentially” are generally interpreted as within 20% of the given value or range, or interpreted as within 10%, 5%, 3%, 2%, 1%, or 0.5% of a given value or range.

As used herein, the terms “film” and/or “layer” may refer to any continuous or discontinuous structure and material (such as materials deposited by the methods disclosed herein). For example, films and/or layers may include two-dimensional materials, three-dimensional materials, nanoparticles, or even partial or complete molecular layers, or partial or complete atomic layers, or clusters of atoms and/or molecules. The film or the layer may include a material or a layer having pinholes, and may be at least partially continuous.

Although the terms first, second, third . . . may be used to describe various constituent elements, the constituent elements are not limited to these terms. These terms are used to distinguish a single element from other constituent elements in the specification. The same terms may be not used in the claims, but are replaced by first, second, third . . . in the order in which elements are declared in the claims. Therefore, in the following description, a first constituent element may be a second constituent element in the claims.

Unless otherwise defined, all terms (including technical and scientific terms) used herein have the same meaning as commonly understood by one of ordinary skill in the art to which this disclosure belongs. It may be understood that these terms, such as those defined in commonly used dictionaries, should be interpreted as having a meaning consistent with the background or context of the related techniques and the disclosure, and should not be interpreted in an idealized or overly formal manner, unless otherwise defined herein.

It should be noted that, in the following embodiments, without departing from the spirit of the disclosure, technical features in several different embodiments may be replaced, reorganized, and mixed to complete other embodiments.

An electronic device of the disclosure may include a power module, a semiconductor device, a semiconductor packaging device, a display device, an antenna device, a sensing device, a light-emitting device, or a tiling device, but not limited thereto. The electronic device may include a bendable or flexible electronic device. The electronic device may include an electronic element. The electronic element may include a passive element, an active element, or a combination of the above, such as a capacitor, a resistor, an inductor, a variable capacitor, a filter, a diode, a transistor, a sensor, a microelectromechanical system element (MEMS), a liquid-crystal chip, etc., but not limited thereto. The diode may include a light-emitting diode or a non-light-emitting diode. The diode includes a P-N junction diode, a PIN diode, or a constant current diode. The light-emitting diode may include, for example, an organic light-emitting diode (OLED), a mini LED, a micro LED, a quantum dot LED, fluorescence, phosphor, or other suitable materials, or a combination of the above, but not limited thereto. The sensor may include, for example, a capacitive sensor, an optical sensor, an electromagnetic sensor, a fingerprint sensor (FPS), a touch sensor, an antenna, or a pen sensor, but not limited thereto. In the following, the display device is used as the electronic device to illustrate the content of the disclosure, but the disclosure is not limited thereto. According to an embodiment of the disclosure, the provided manufacturing method of the electronic device may be applied, for example, to a wafer-level package (WLP) or a panel-level package (PLP) process, and the chip-first process or the chip-last (RDL-first) process may be adopted, which is further described in detail below. The electronic device referred to in the disclosure may include a system-on-package (SoC), a system-in-package (SiP), an antenna-in-package (AiP), or a combination of the above, but not limited thereto.

Reference will now be made in detail to the exemplary embodiments of the disclosure, and examples of the exemplary embodiments are illustrated in the accompanying drawings. Wherever possible, the same reference numerals are used in the figures and the descriptions to refer to the same or similar portions.

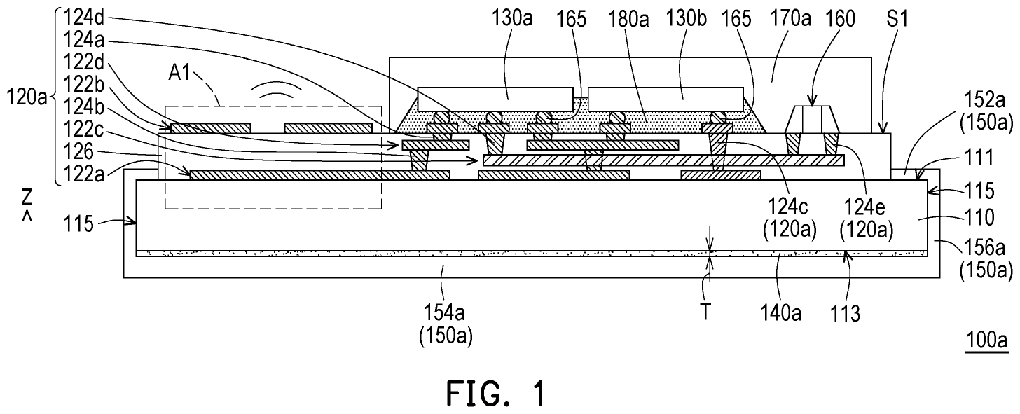

FIG. 1 is a schematic cross-sectional view of an electronic device of an embodiment of the disclosure. Please refer to FIG. 1. In the present embodiment, an electronic device 100a includes a substrate 110, a circuit layer 120a, at least one electronic unit (two electronic units 130a and 130b are schematically shown), a stress adjustment layer 140a, and a buffer layer 150a. The substrate 110 has a first surface 111 and a second surface 113 opposite to each other and at least one side (two sides 115 are schematically shown) connected to the first surface 111 and the second surface 113. The circuit layer 120a is disposed on the first surface 111 of the substrate 110. The electronic units 130a and 130b are electrically connected to the circuit layer 120a. The stress adjustment layer 140a is disposed on the second surface 113 of the substrate 110. The buffer layer 150a surrounds the substrate 110, wherein the stress adjustment layer 140a is located between the substrate 110 and the buffer layer 150a, and the buffer layer 150a is in contact with the at least one side 115 of the substrate 110.

Specifically, the electronic device 100a of the present embodiment may be applied to a power module, a semiconductor packaging device, a display device, a light-emitting device, a backlight device, an antenna device, a sensing device, or a tiling device, but not limited thereto. The substrate 110 may be a single layer or multiple layers. The substrate 110 may include a rigid substrate or a flexible substrate, such as a glass substrate, a silicon substrate, a printed circuit board, or a flexible printed circuit board, but not limited thereto. In an embodiment, the thickness of the substrate 110 is, for example, 0.1 millimeters (mm) to 1.1 mm, but not limited thereto. In an embodiment, the substrate 110 may be used to carry an element disposed on the substrate 110. In an embodiment, the thermal expansion coefficient of the substrate 110 may be, for example, 0.01 ppm/K to 30 ppm/K.

The circuit layer 120a may be directly disposed on the first surface 111 of the substrate 110, that is, the circuit layer 120a is directly in contact with the first surface 111 of the substrate 110. The circuit layer 120a may be, for example, a redistribution structure (RDL), and may include at least one conductive layer (conductive layers 122a, 122b, 122c, 122d are schematically shown), at least one conductive via (a plurality of conductive vias 124a, 124b, 124c, 124d, 124e are schematically shown), and at least one insulating layer (an insulating layer 126 is schematically shown) stacked on each other along the normal direction of the electronic device 100a (Z direction), wherein the normal direction of the electronic device 100a may also be regarded as the normal direction of the electronic units 130a and 130b or the substrate 110. As shown in FIG. 1, the conductive layer 122a, the insulating layer 126, and the conductive layer 122b may form an antenna unit A1. The conductive via 124a is electrically connected to the conductive layer 122b and the conductive layer 122d, and the conductive via 124b is electrically connected to the conductive layer 122d and the conductive layer 122a. The conductive via 124c is electrically connected to the conductive layer 122b and the conductive layer 122a, and the conductive via 124d is electrically connected to the conductive layer 122b and the conductive layer 122c. In an embodiment, the substrate 110 and the circuit layer 120a may form a circuit structure, wherein the thermal expansion coefficient of the substrate 110 may be less than the thermal expansion coefficient of the insulating layer 126 of the circuit layer 120a, but not limited thereto. In an embodiment, the size of the circuit layer 120a may be less than the size of the substrate 110, meaning the circuit layer 120a exposes a portion of the first surface 111 of the substrate 110, but not limited thereto. In an embodiment, the thickness of the insulating layer 126 is, for example, 0.1 micrometers (μm) to 30 micrometers, or, for example, 1 micrometer (μm) to 15 micrometers, but not limited thereto. In an embodiment, the dielectric loss of the insulating layer 126 at 10 GHz may be less than 0.1. In an embodiment, the thermal expansion coefficient of the insulating layer 126 may be, for example, 10 ppm/K to 50 ppm/K. The material of the insulating layer 126 may include an organic material, an inorganic material, or a combination of the above, and may include polyimide (PI), photosensitive polyimide (PSPI), build-up film (ABF), polymer, resin (epoxy), silicon oxide, silicon nitride, a combination of the above, or other suitable insulating materials, but not limited thereto. In an embodiment, the conductive layers 122a, 122b, 122c, 122d or the conductive vias 124a, 124b, 124c, 124d, 124e are single-layer or multi-layer conductive material stacks, and the conductive layers 122a, 122b, 122c, 122d or the conductive vias 124a, 124b, 124c, 124d, 124e may include a seed layer to improve the bonding ability between the subsequent film layer and the insulating layer, but not limited thereto. The thickness of the conductive layers 122a, 122b, 122c, 122d is, for example, 0.1 micrometers (μm) to 30 micrometers, or, for example, 1 micrometer (μm) to 15 micrometers, but not limited thereto. In an embodiment, the thermal expansion coefficient of the conductive layers 122a, 122b, 122c, 122d may be, for example, 10 ppm/K to 50 ppm/K. The material of the conductive layers 122a, 122b, 122c, 122d or the conductive vias 124a, 124b, 124c, 124d, 124e may include titanium, titanium nitride, tantalum, copper, nickel, gold, or a combination of the above or other suitable conductive materials, but not limited thereto.

In an embodiment, the electronic unit 130a may be, for example, a substrate integrated circuit, and the electronic unit 130b may be, for example, a memory, but not limited thereto. In an embodiment, the electronic units 130a and 130b may be electrically connected to the circuit layer 120a via the connecting element 165 respectively. Moreover, the electronic device 100a may further include at least one passive element (one passive element 160 is schematically shown) electrically connected to the at least one electronic unit 130a and 130b via the circuit layer 120a. In an embodiment, the conductive via 124e of the circuit layer 120a is electrically connected to the conductive layer 122c and the passive element 160. In an embodiment, the passive element 160 may be, for example, a surface mount device (SMD), a capacitor, an inductor, a resistor, or other suitable electronic elements, but not limited thereto. In other words, the circuit layer 120a may be electrically connected to the electronic units 130a and 130b or each electronic element (such as the passive element 160) via the connecting element 165 or other joint elements. In an embodiment, the circuit layer 120a may also, for example, redistribute the circuits and/or further increase the circuit fan-out area, or, different electronic elements may be electrically connected to each other via the circuit layer 120a, and the type of the circuit layer 120a is not limited here. For example, the circuit layer 120a may be applied to wafer-level chip-scale package (WLCSP), wafer-level package (WLP), panel-level package (PLP), or other electronic device manufacturing methods, but not limited thereto.

Please refer further to FIG. 1. The stress adjustment layer 140a of the present embodiment may be directly disposed on the second surface 113 of the substrate 110 and is located between the substrate 110 and the buffer layer 150a. In an embodiment, the material of the stress adjustment layer 140a may be, for example, silicon oxide (SiOx), silicon nitride (SiNx), a combination of the above, or other suitable materials. In an embodiment, the thermal expansion coefficient of the stress adjustment layer 140a may be, for example, 0.01 ppm/K to 12 ppm/K. In an embodiment, a thickness T of the stress adjustment layer 140a may be, for example, between 0.1 microns and 10 microns, but not limited thereto. In an embodiment, the stress adjustment layer 140a is, for example, an anti-warp layer, wherein the warping direction of the stress adjustment layer 140a may be opposite to the warping direction of the circuit layer 120a to reduce warping, so that the electronic device 100a may have better structural reliability. In an embodiment, the stress adjustment layer 140a may include a single layer or a multi-layer stack. For example, a silicon oxide layer may be formed first at the surface of the substrate 110, and then a silicon nitride layer is formed at the surface of the silicon oxide layer, so that the substrate 110, the silicon oxide layer, and the silicon nitride layer form a unique sandwich structure, wherein the silicon nitride layer and the silicon oxide layer may be different, thereby avoiding oxidation of the silicon oxide layer and reducing the risk of a brittle silicon oxide layer, thus improving the reliability of the electronic device 100a, but not limited thereto. In an embodiment, the width of the circuit layer 120a is less than the width of the substrate 110, or the ratio of the width of the circuit layer 120a to the width of the substrate 110 is greater than or equal to 80% and less than or equal to 98% to reduce warpage.

Furthermore, in the present embodiment, the buffer layer 150a surrounds the substrate 110 and is in contact with the at least one side 115 of the substrate 110. Furthermore, the buffer layer 150a of the present embodiment includes a first portion 152a, a second portion 154a, and a third portion 156a. The first portion 152a is disposed at the first surface 111 of the substrate 110. The stress adjustment layer 140a is located between the substrate 110 and the second portion 154a. The third portion 156a is connected to the first portion 152a and the second portion 154a, and the third portion 156a is in contact with the at least one side 115. In an embodiment, the first portion 152a, the second portion 154a, and the third portion 156a may be continuous structural layers, or may be discontinuous structural layers, which is not limited thereto. In an embodiment, the Young's modulus of the buffer layer 150a may be less than the Young's modulus of the stress adjustment layer 140a. That is, the hardness of the buffer layer 150a may be less than the hardness of the stress adjustment layer 140a, the Young's modulus of the buffer layer 150a may be between 0.1 GPa and 10 GPa, and the Young's modulus of the stress adjustment layer 140a may be between 20 GPa and 1000 GPa. In an embodiment, the hardness of the buffer layer 150a may also be less than the hardness of the substrate 110. In an embodiment, the material of the buffer layer 150a may be, for example, an organic material or a polymer, and the thickness thereof may be, for example, 1 micron to 20 microns, but not limited thereto. The buffer layer 150a has toughness or flexibility, and therefore may effectively reduce breakage of the substrate 110 due to impact.

In addition, the electronic device 100a of the present embodiment may also optionally include an encapsulation layer 170a surrounding the electronic units 130a and 130b. In the present embodiment, the encapsulation layer 170a also surrounds the passive element 160. In the present embodiment, the encapsulation layer 170a is directly in contact with and covers the electronic units 130a and 130b and the passive element 160, for example. That is, the electronic units 130a and 130b and the passive element 160 are sealed in the encapsulation layer 170a. In an embodiment, the material of the encapsulation layer 170a is, for example, epoxy molding compound (EMC), wherein the encapsulation layer 170a is formed by, for example, a molding process, but not limited thereto.

In addition, the electronic device 100a of the present embodiment may further include an adhesive layer 180a disposed between the electronic units 130a and 130b and the circuit layer 120a. In an embodiment, the adhesive layer 180a may be, for example, an underfill directly in contact with the active surfaces of the electronic units 130a and 130b and a surface S1 of the circuit layer 120a relatively far away from the substrate 110, and is filled in the space between two adjacent connecting elements 165. In an embodiment, the adhesive layer 180a is used to protect the connecting elements 165 or ensure the bonding between the electronic units 130a and 130b and the circuit layer 120a.

In an embodiment, the material of the adhesive layer 180a may be, for example, resin, epoxy resin, or molding compound, but not limited thereto. In an embodiment, the connecting elements 165 may include copper, nickel, tin, silver, gold, gallium, or a combination thereof, but not limited thereto.

In short, in the present embodiment, the circuit layer 120a and the stress adjustment layer 140a are respectively disposed on the first surface 111 and the second surface 113 of the substrate 110, the electronic units 130a and 130b are electrically connected to the circuit layer 120a, the stress adjustment layer 140a is located between the substrate 110 and the buffer layer 150a, and the buffer layer 150a surrounds the substrate 110 and is in contact with the at least one side 115 of the substrate 110. Via the above design, the joint strength between elements may be improved, or the distance between elements may be shorter, thereby improving the signal transmission quality of the electronic device 100a. Furthermore, since the electronic device 100a of the present embodiment is provided with the stress adjustment layer 140a, the stress may be effectively balanced to reduce board warpage, thereby increasing structural reliability. In addition, the electronic device 100a of the present embodiment is provided with the buffer layer 150a to provide buffering to effectively reduce breakage of the substrate 110 due to impact.

It should be mentioned that, the embodiments below adopt the same reference numerals and portions of the content from previous embodiments. Specifically, the same reference numerals are used to represent the same or similar elements, and the descriptions for the same techniques are omitted. The omitted portions are as described in the embodiments above and are not repeated in the embodiments below.

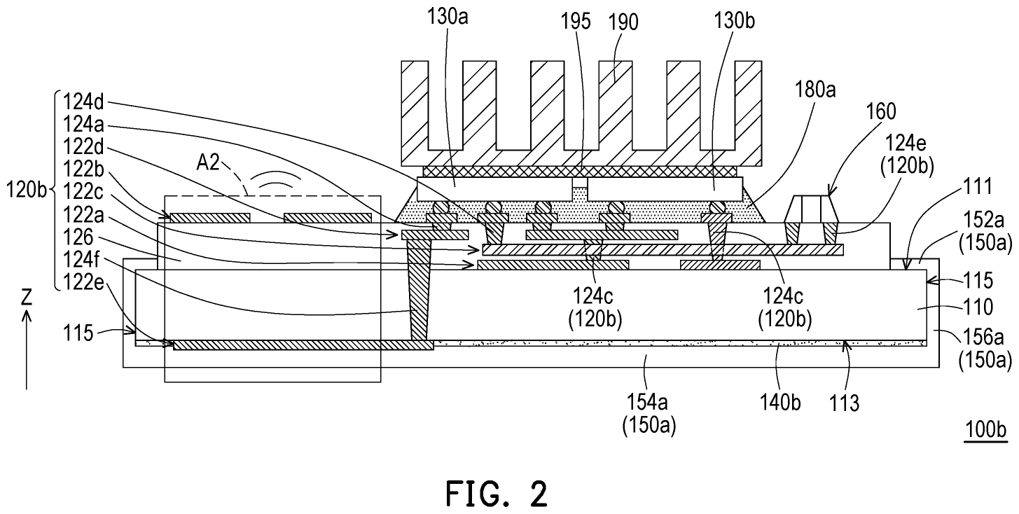

FIG. 2 is a schematic cross-sectional view of an electronic device of another embodiment of the disclosure. Please refer to FIG. 1 and FIG. 2 at the same time. An electronic device 100b of the present embodiment is similar to the electronic device 100a of FIG. 1. The difference between the two is: in the present embodiment, the encapsulation layer 170a is not disposed at the back surfaces of the electronic units 130a and 130b. In detail, the electronic device 100b of the present embodiment further includes a heat dissipation assembly 190 disposed on the electronic units 130a and 130b. In an embodiment, the heat dissipation assembly 190 may be, for example, a heat dissipation fin, but not limited thereto. Furthermore, the electronic device 100b of the present embodiment may further include a thermal conductive layer 195 disposed between the heat dissipation assembly 190 and the electronic units 130a and 130b. The heat dissipation assembly 190 is fixed on the back surfaces of the electronic units 130a and 130b via the thermal conductive layer 195, and may transfer the heat generated by the electronic units 130a and 130b to the outside world. In an embodiment, the thermal conductive layer 195 may be, for example, thermal conductive adhesive or heat dissipation adhesive, but not limited thereto. In an embodiment, the thermal conductive layer 195 may further include a silicon carbide particle, but not limited thereto. In addition, the circuit layer 120b of the present embodiment also includes a conductive layer 122e and a conductive via 124f. The conductive layer 122e and the stress adjustment layer 140b of the circuit layer 120b are disposed on the second surface 113 of the substrate 110, and the conductive via 124f passes through the insulating layer 126 and the substrate 110 to be electrically connected to the conductive layer 122d and the conductive layer 122e. Here, the conductive layer 122b, the insulating layer 126, the substrate 110, and the conductive layer 122e may form an antenna unit A2. Generally, the wavelength reception of an antenna comes from the thickness thereof. Here, the thickness of the antenna unit A2 includes the thickness to the substrate 110, wherein if the substrate 110 is a glass substrate, compared with a general dielectric material, characteristics such as low dielectric constant (Dk) and low dissipation coefficient (Df), low heat accumulation, and environmentally friendly material may be achieved, or the antenna unit A2 may have better signal transmission effects.

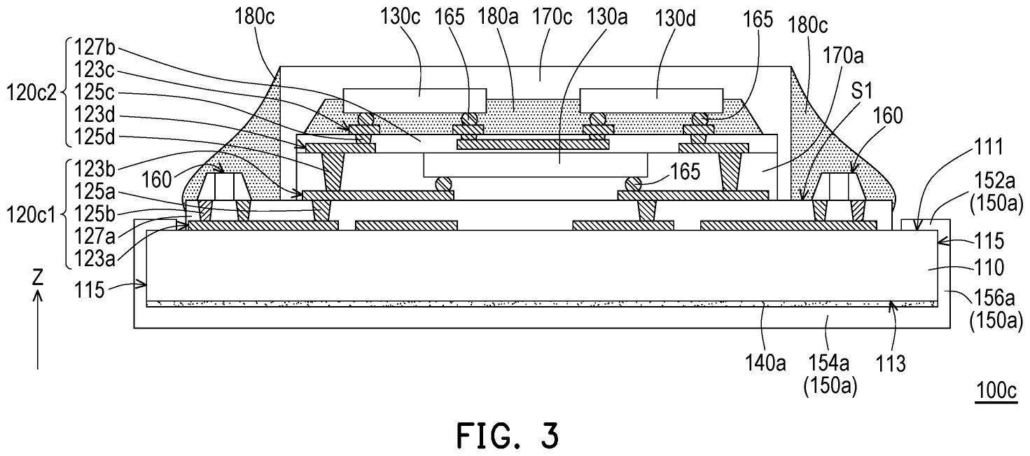

FIG. 3 is a schematic cross-sectional view of an electronic device of another embodiment of the disclosure. Please refer to FIG. 1 and FIG. 3 at the same time. An electronic device 100c of the present embodiment is similar to the electronic device 100a of FIG. 1. The difference between the two is that in the present embodiment, the electronic unit 130a is located between a circuit layer 120cl and a circuit layer 120c2, and the electronic units 130c and 130d are disposed on the circuit layer 120c2, wherein the electronic units 130a, 130c, and 130d are electrically connected to each other via the circuit layers 120c1 and 120c2.

Specifically, the circuit layer 120cl of the present embodiment is, for example, a redistribution structure layer disposed on the first surface 111 of the substrate 110 and including at least one conductive layer (the conductive layers 123a and 123b are schematically shown), at least one conductive via (a plurality of conductive vias 125a and 125b are schematically shown), and at least one insulating layer (an insulating layer 127a is schematically shown). The conductive via 125a is electrically connected to the conductive layer 123a and the conductive layer 123b, and the conductive via 125b is electrically connected to the conductive layer 123a and the passive element 160. The electronic unit 130a may be, for example, a base integrated circuit (IC), and may be electrically connected to the circuit layer 120cl via the connecting elements 165. The encapsulation layer 170a surrounds the electronic unit 130a, that is, the encapsulation layer 170a is in contact with at least one side of the electronic unit 130a, wherein the encapsulation layer 170a is aligned with the back surface of the electronic unit 130a, and covers the connecting element 165 and the conductive layer 123b of the circuit layer 120a.

Moreover, the circuit layer 120c2 is, for example, a redistribution structure layer disposed on the back side of the electronic unit 130a and the encapsulation layer 170a and includes at least one conductive layer (the conductive layers 123c and 123d are schematically shown), at least one conductive via (a plurality of conductive vias 125c and 125d are schematically shown), and at least one insulating layer (an insulating layer 127b is schematically shown). The conductive via 125c is electrically connected to the conductive layer 123c and the conductive layer 123d, and the conductive via 125d penetrates the encapsulation layer 170a and is electrically connected to the conductive layer 123d and the conductive layer 123b. The electronic units 130c and 130d may each be a chip, for example, and are electrically connected to the circuit layer 120cl via the connecting element 165. The adhesive layer 180a is disposed between the electronic units 130c and 130d and the circuit layer 120c2, and is filled in the space between two adjacent connecting elements 165. Moreover, the electronic device 100c of the present embodiment may also optionally include an encapsulation layer 170c surrounding the electronic units 130c and 130d and directly sealing the electronic units 130c and 130d, the adhesive layer 180a, the circuit layer 120c2, and the encapsulation layer 170a therein. Moreover, the electronic device 100c of the present embodiment may also optionally include an adhesive layer 180c. The adhesive layer 180c may have a curved surface and be connected to the encapsulation layer 170c and cover the passive element 160 to avoid breakage or to protect the passive element 160. In an embodiment, the material of the adhesive layer 180c may be, for example, resin, epoxy resin, or molding compound, but not limited thereto.

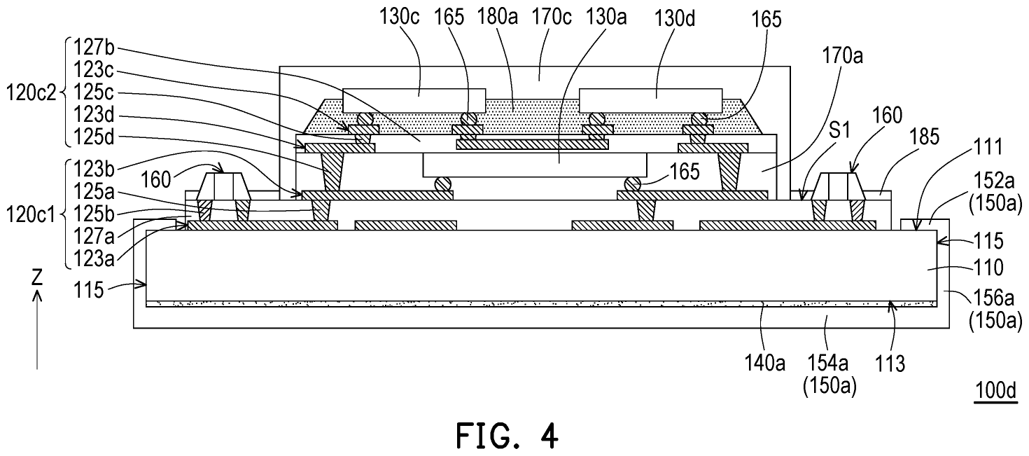

FIG. 4 is a schematic cross-sectional view of an electronic device of another embodiment of the disclosure. Please refer to FIG. 3 and FIG. 4 at the same time. An electronic device 100d of the present embodiment is similar to the electronic device 100c of FIG. 3. The difference between the two is: in the present embodiment, the electronic device 100d may further include an insulating layer 185 covering the surface S1 of the circuit layer 120cl far away from the substrate 110. In an embodiment, the material of the insulating layer 185 is, for example, green paint, photosensitive dielectric material, ABF film, and polymer resin material, but not limited thereto. In an embodiment, the insulating layer 185 may be, for example, a solder mask and may be used to protect the conductive layer from being oxidized when directly exposed to the atmospheric environment or accidentally being stained by solder and affecting the function of the circuit layer 120c1.

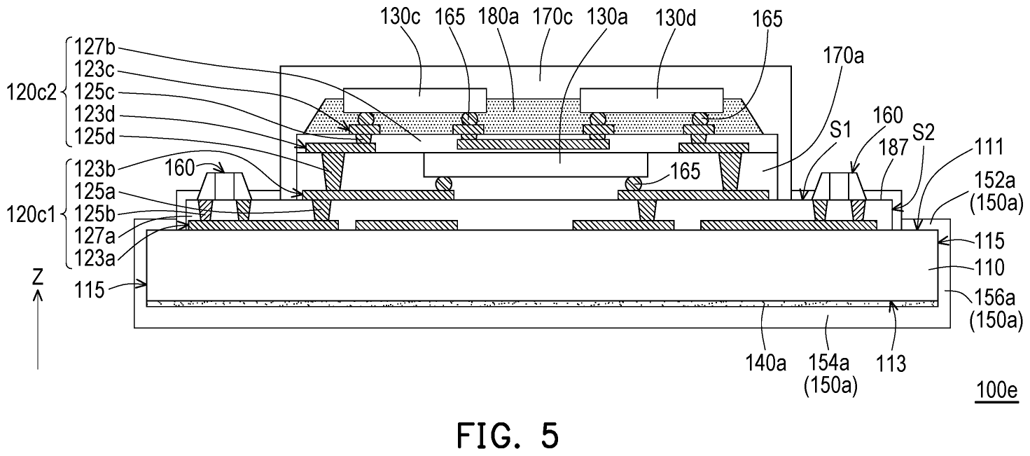

FIG. 5 is a schematic cross-sectional view of an electronic device of another embodiment of the disclosure. Please refer to FIG. 3 and FIG. 5 at the same time. An electronic device 100e of the present embodiment is similar to the electronic device 100c of FIG. 3. The difference between the two is: in the present embodiment, the electronic device 100e may further include an insulating layer 187 covering the surface S1 of the circuit layer 120cl relatively far from the substrate 110 and the side S2 connected to the surface S1. In an embodiment, the insulating layer 187 may be connected to the buffer layer 150a and surround the circuit layer 120cl and the substrate 110 therein. In an embodiment, the material of the insulating layer 187 is, for example, green paint, photosensitive dielectric material, ABF film, and polymer resin material, but not limited thereto.

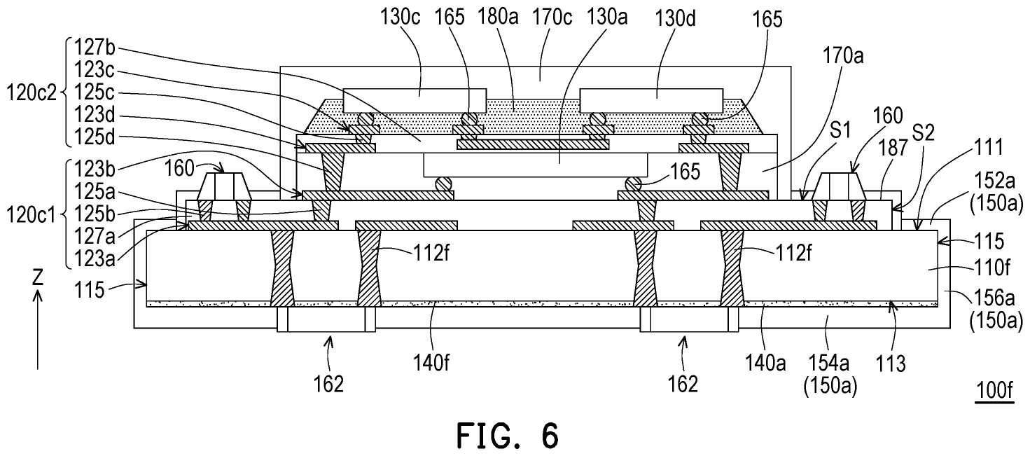

FIG. 6 is a schematic cross-sectional view of an electronic device of another embodiment of the disclosure. Please refer to FIG. 5 and FIG. 6 at the same time. An electronic device 100f of the present embodiment is similar to the electronic device 100e of FIG. 5. The difference between the two is: in the present embodiment, the electronic device 100f also includes a passive element 162 disposed on the second surface 113 of the substrate 110f. The substrate 110f of the present embodiment may also include a conductive via 112f penetrating the substrate 110 and electrically connected to the conductive layer 123a of the circuit layer 120cl and the passive element 162. In an embodiment, the conductive via 112f is a through-glass-via (TGV), but not limited thereto.

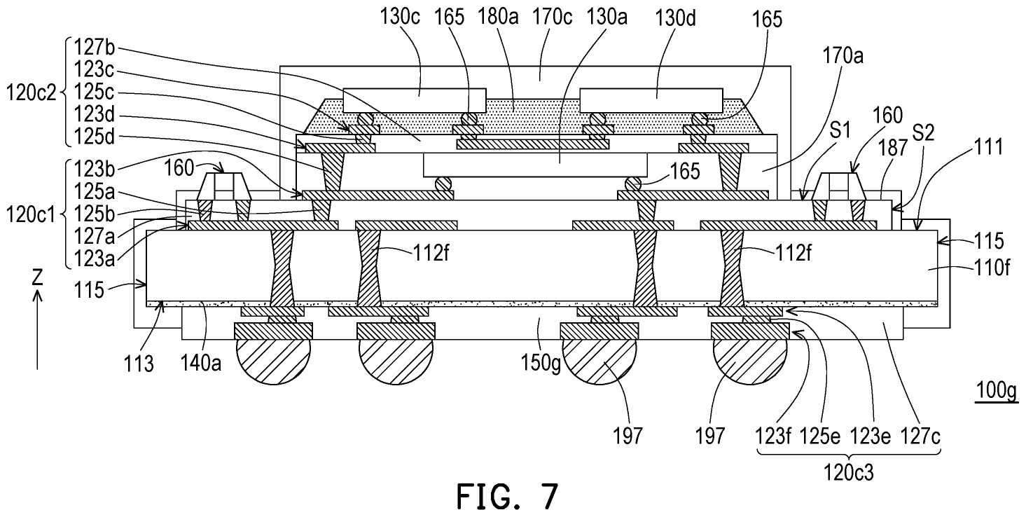

FIG. 7 is a schematic cross-sectional view of an electronic device of another embodiment of the disclosure. Please refer to FIG. 6 and FIG. 7 at the same time. An electronic device 100g of the present embodiment is similar to the electronic device 100f of FIG. 6. The difference between the two is that in the present embodiment, the electronic device 100g may further include a circuit layer 120c3, which is, for example, a redistribution structure layer including at least one conductive layer (the conductive layers 123e and 123f are schematically shown), at least one conductive via (a plurality of conductive vias 125e are schematically shown), and at least one insulating layer (an insulating layer 127c is schematically shown). The conductive via 112f is electrically connected to the conductive layer 123a and the conductive layer 123e, and the conductive via 125e is electrically connected to the conductive layer 123e and the conductive layer 123f. In addition, the electronic device 100g of the present embodiment further includes a connecting element 197 electrically connected to the conductive layer 123f of the circuit layer 120c3. In an embodiment, the buffer layer 150g may be connected to the insulating layer 187 and the insulating layer 127c of the circuit layer 120c3, but not limited thereto. The buffer layer 150g is in contact with the side of the substrate 110, and at least a portion of the stress buffer layer 140a is disposed between the substrate 110f and the buffer layer 150g.

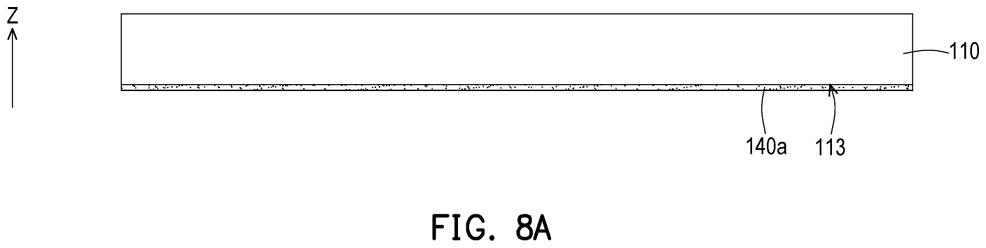

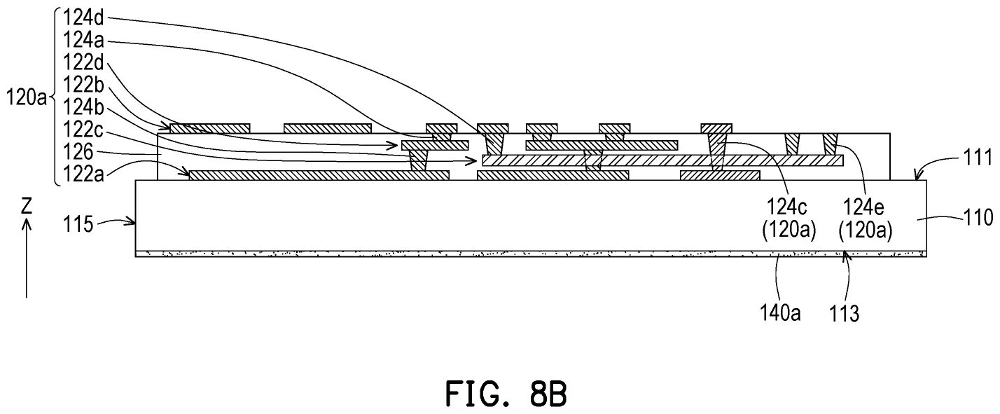

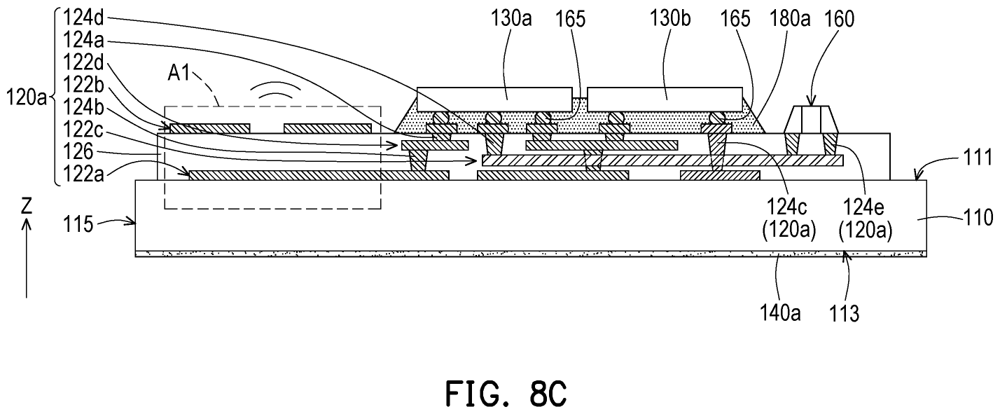

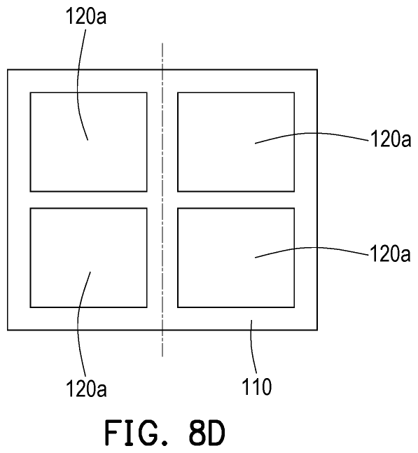

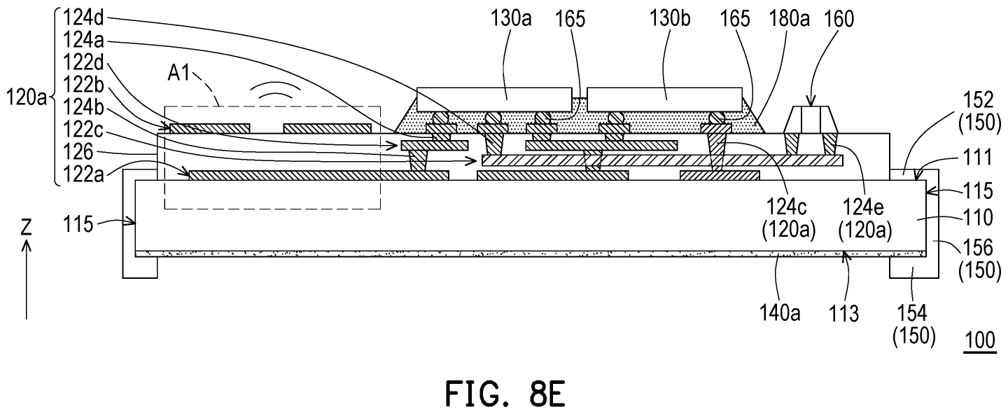

FIG. 8A to FIG. 8E are schematic diagrams of a manufacturing method of an electronic device of an embodiment of the disclosure. It should be noted that, for the sake of explanation, FIG. 8A, FIG. 8B, FIG. 8C, and FIG. 8E are shown in cross-sections, and FIG. 8D is a top view of the substrate of FIG. 8C and the circuit layer thereon before and after cutting.

In terms of the manufacturing process, please first refer to FIG. 8A for forming the stress adjustment layer 140a on the second surface 113 of the substrate 110. In an embodiment, the forming may be in direct contact thereon, or indirectly formed thereon via, for example, a seed layer. The method of forming the stress adjustment layer 140a includes deposition, sputtering, or other suitable process methods. Next, please refer to FIG. 8B for forming the circuit layer 120a on the first surface 111 of the substrate 110. The circuit layer 120a may include at least one conductive layer (the conductive layers 122a, 122b, 122c, 122d are schematically shown), at least one conductive via (the plurality of conductive vias 124a, 124b, 124c, 124d, 124e are schematically shown), and at least one insulating layer (the insulating layer 126 is schematically shown) along the normal direction of the substrate 110 (Z-direction stacking). The method of forming the circuit layer includes deposition, sputtering, electroplating, coating, laminating, photolithography, development, etching, laser, grinding, a combination of the above, or other suitable process methods, but not limited thereto. Next, please refer to FIG. 8C, the electronic units 130a and 130b are disposed on the circuit layer 120a via the connecting element 165, wherein the electronic units 130a and 130b are electrically connected to the circuit layer 120a via the connecting element 165. The method of completing the bonding of the electronic units and the connecting element includes bonding, chip transfer, reflow, a combination of the above, or other suitable process methods, but not limited thereto. Next, an adhesive layer 180a is formed between the electronic units 130a and 130b and the circuit layer 120a, wherein the adhesive layer 180a covers the connecting element 165 and is filled in the gap between two adjacent connecting elements 165. Here, the conductive layer 122a, the insulating layer 126, and the conductive layer 122b may form the antenna unit A1. Next, the passive element 160 is disposed on the circuit layer 120a, wherein the passive element 160 is electrically connected to the electronic units 130a and 130b via the circuit layer 120a.

Next, please refer to FIG. 8C and FIG. 8D at the same time. After the photoresist on the substrate 110 and the circuit layer 120a thereon are removed, the substrate 110 may be cut, so that the area of the circuit layer 120a may be less than or equal to the area of the substrate 110. For example, the ratio of the area of the circuit layer 120a to the area of the substrate 110 is greater than or equal to 80% and less than or equal to 98% to effectively reduce board warpage. Lastly, referring to FIG. 8E, for example, the buffer layer 150 is formed on at least one side 115 of the substrate 110 by coating, wherein the buffer layer 150 includes a first portion 152, a second portion 154, and a third portion 156. The first portion 152 is disposed at the first surface 111 of the substrate 110. The stress adjustment layer 140a is located between the substrate 110 and the second portion 154. The third portion 156 is connected to the first portion 152 and the second portion 154, and the third portion 156 is in contact with the at least one side 115. At this point, the production of the electronic device 100 is completed.

It should be mentioned that the process of the electronic device 100 in the present embodiment may be applied, for example, to a wafer-level package (WLP) or panel-level package (PLP) process and may be chip first or chip last (RDL first), and is not limited here. In addition, the order in which the electronic units 130a and 130b, the antenna unit A1, and the passive element 160 are disposed may be self-adjusted according to process requirements, and is not limited here.

Based on the above, in an embodiment of the disclosure, the circuit layer and the stress adjustment layer are respectively disposed on the first surface and the second surface of the substrate, the electronic unit is electrically connected to the circuit layer, the stress adjustment layer is located between the substrate and the buffer layer, and the buffer layer surrounds the substrate and is contact with at least one side of the substrate. Via the above design, integrating elements on a substrate may make the distance between elements shorter, or may increase the joint strength between elements, thereby improving the signal transmission quality of the electronic device. Furthermore, since the electronic device of an embodiment of the disclosure is provided with the stress adjustment layer, board warpage may be effectively reduced and structural reliability may be increased. In addition, the electronic device of an embodiment of the disclosure is provided with the buffer layer to provide buffering to effectively reduce breakage of the substrate due to impact.

Although the disclosure has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. An electronic device, comprising:
a substrate having a first surface and a second surface opposite to each other and at least one side connected to the first surface and the second surface;
a circuit layer disposed on the first surface of the substrate;
at least one electronic unit electronically connected to the circuit layer;
a stress adjustment layer disposed on the second surface of the substrate; and
a buffer layer surrounding the substrate, wherein the stress adjustment layer is located between the substrate and the buffer layer, and the buffer layer is in contact with the at least one side of the substrate.

2. The electronic device of claim 1, wherein the buffer layer comprises:
a first portion disposed at the first surface;
a second portion, wherein the stress adjustment layer is located between the substrate and the second portion; and
a third portion connected to the first portion and the second portion, and the third portion is in contact with the at least one side.

3. The electronic device of claim 1, wherein a Young's modulus of the buffer layer is less than a Young's modulus of the stress adjustment layer.

4. The electronic device of claim 1, further comprising:
at least one passive element electrically connected to the at least one electronic unit via the circuit layer.

5. The electronic device of claim 4, further comprising:
an encapsulation layer surrounding the at least one passive element.

6. The electronic device of claim 1, further comprising:
an encapsulation layer surrounding the at least one electronic unit.

7. The electronic device of claim 1, further comprising:
an adhesive layer disposed between the at least one electronic unit and the circuit layer.

8. The electronic device of claim 1, further comprising:
a heat dissipation assembly disposed on the at least one electronic unit.

9. The electronic device of claim 8, further comprising:
a thermal conductive layer disposed between the heat dissipation assembly and the at least one electronic unit.

10. The electronic device of claim 1, wherein a thickness of the stress adjustment layer is between 0.1 microns and 10 microns.

11. The electronic device of claim 1, wherein the circuit layer comprises at least one conductive layer, at least one conductive via, and at least one insulating layer, and a thermal expansion coefficient of the substrate is less than a thermal expansion coefficient of the at least one insulating layer of the circuit layer.

12. The electronic device of claim 11, wherein the thermal expansion coefficient of the substrate is between 0.01 ppm/K and 30 ppm/K.

13. The electronic device of claim 11, wherein the thermal expansion coefficient of the at least one insulating layer is between 10 ppm/K and 50 ppm/K.

14. The electronic device of claim 11, wherein the thermal expansion coefficient of the at least one conductive layer is between 10 ppm/K and 50 ppm/K.

15. The electronic device of claim 1, wherein the thermal expansion coefficient of the stress adjustment layer is between 0.01 ppm/K and 12 ppm/K.

16. The electronic device of claim 1, wherein a thickness of the stress adjustment layer is between 0.1 microns and 10 microns.

17. The electronic device of claim 1, wherein a warping direction of the stress adjustment layer is opposite to a warping direction of the circuit layer.

18. The electronic device of claim 1, wherein a ratio of a width of the circuit layer to a width of the substrate is greater than or equal to 80% and less than or equal to 98%.

19. The electronic device of claim 1, wherein a hardness of the buffer layer is less than a hardness of the substrate.

20. The electronic device of claim 1, wherein a width of the circuit layer is less than a width of the substrate.
